(19) United States
(12) Patent Application Publication
(10) Pub. No.: US 2026/0211005 A1
(43) Pub. Date: Jul. 23, 2026

(54) Electrical component and method for manufacturing such an electrical component

(71) Applicant: Schneider Electric Industries SAS, Rueil Malmaison (FR)

(72) Inventors: Christophe CHANVILLARD, Eybens (FR); Loïc RONDOT, Meylan (FR); Stéphane WOLOZAN, Echirolles (FR)

(21) Appl. No.: 19/140,891

(22) PCT Filed: Dec. 20, 2023
(86) PCT No.: PCT/EP2023/086819

§ 371 Date: Jun. 18, 2025

(30) Foreign Application Priority Data
Dec. 21, 2022 (FR) FR2214109

(51) Int. Cl. G01R 15/18; H01F 5/02; H01F 5/04; H01F 27/00; H01F 27/28; H01F 41/08; H01F 41/10

(52) U.S. Cl. CPC G01R 15/181; H01F 5/02; H01F 5/04; H01F 27/006; H01F 27/2828; H01F 41/08; H01F 41/10

(57) ABSTRACT

The invention relates to an electrical component (10) comprising a plastronic armature (12), a printed circuit board (14) to which the armature is attached and an unbranched electrical line comprising segments (46A-46D, 48A-48D) carried by the armature and by the printed circuit board. In order to facilitate the manufacture of the electrical component, the armature comprises four arms (26A-26D) distributed in a loop around an opening (16), each one of which arms carries a segment, and four joints (28A-28D) connecting the arms, and the printed circuit board comprises four branches that are distributed in a loop around the opening, each one of which branches carries a segment. Moreover, the electrical component comprises contact pads (50A-50D, 50A′-50D′) carried by the armature, each one of which contact pads is arranged at a joint of the armature. Each junction between two consecutive segments of the electrical line, one of the two consecutive segments of which is carried by an arm of the armature and the other of the two consecutive segments of which is carried by a branch of the printed circuit board, is formed by one of the contact pads.

### CROSS-REFERENCE TO RELATED APPLICATIONS

This patent application is a U.S. national stage application of International Application No. PCT/EP2023/086819, filed Dec. 20. 2023, which claims the benefit of French Patent Application No. 2214109, filed Dec. 21, 2022, the entire disclosures of which are incorporated by reference herein.

### BACKGROUND

The present invention concerns an electrical component and a method for manufacturing such an electrical component.

An electric current sensor is used to measure the intensity of an electric current circulating in an electric line. Such a measurement can prove necessary to quantify the power and/or the electrical energy consumed by an electric receiver or to detect an operating anomaly of the receiver. It is known to use as a sensor a Rogowski type current sensor that employs one or more conductive wire windings around an amagnetic core, this type of sensor generally being associated with a circuit for processing the signal including an integrator circuit.

The sensor may for example take the form of a conductive winding that extends along a circular or rectangular trajectory. There is therefore obtained for example a toric winding that forms a loop. In use the electric line the intensity of the current in which has to be measured is positioned so as to pass through the loop traced out by the winding at the center of the trajectory. The electric line is then radially surrounded by the winding. To reduce interference with the measurement either the winding can comprise go turns that cross return turns or the return turns are wound inside or in parallel under the go turns or a non-wound part of the conductor emanating from one end of the go turns winding passes again through the interior of the winding along the trajectory of said winding in the opposite direction. EP3171182A1 provides a few examples of this.

To construct this type of winding a copper wire is traditionally wound around a toric polymer plastic material core to form the go turns, providing a non-wound return conductor situated inside the core or on the surface of the core between the go turns. Now, the accuracy of the measurement from a Rogowski type current sensor depends in particular on the accuracy of the geometry of the turns and on the regularity of their spatial arrangement and the gain of such a sensor increases with the number and the size of turns in the winding. To obtain a high turns density and for precise control of the positioning of the turns it is therefore necessary to provide complex and costly machines for winding the conductive wire. Furthermore, the wound conductor is liable to become deformed in use, for example because of the effect of thermal stresses, reducing the performance of the sensor.

To address these disadvantages it is also known to construct this type of winding on a multilayer printed circuit board, the turns being formed by conductive tracks on the surface and within the thickness of the printed circuit board, as described in FR 3 075 387 A1. Such an approach is globally satisfactory and makes it possible to obtain a current sensor that is more robust and the manufacture of which can easily be industrialized, but the performance of the current sensor is limited by the density of the turns, itself constrained by the method of manufacturing the printed circuit board, which prevents forming turns of high thickness.

Another known approach, for example from FR 3 109 637 A1, is to manufacture a plastronic current sensor with an armature formed of a polymer plastic material and an organometallic additive, comprising two parallel rectilinear branches on the surface of which windings are formed with the aid of conductive tracks. Two bars made of ferromagnetic material extend between the branches so as to obtain a magnetic circuit in the form of a loop. Such an approach enables a sensor of high performance to be obtained with a high density of turns but necessitates recourse to costly methods of manufacture. Indeed, the ferromagnetic material used to manufacture the bars is particularly costly. Furthermore, this material behaves as an amplifier that amplifies defects linked in particular to the positioning of the bars and it is therefore necessary to control the positioning of the bars precisely to prevent the performance of the sensor being degraded.

FR 3 109 637 A1 describes another approach consisting in proposing a current sensor the armature of which is of annular shape, turns being formed around all of the circumference of the armature, the current sensor then including no bars. The return turns are formed on a printed circuit board on which the armature is positioned. However, FR 3 109 637 A1 provides no information as to the means for manufacturing such a current sensor.

Furthermore, the annular shape makes the manufacture of the current sensor and its integration into an electronic circuit complicated and does not facilitate positioning the connections between the turns formed on the armature and on the printed circuit board, and the positioning of these connections leads to a loss of symmetry of the current sensor. In particular this loss of symmetry leads to sensitivity to the position of the conductor because if the conductor is not perfectly centered relative to the annular shape armature the gain is not homogeneous at the center of the current sensor, and also leads to reduction of the immunity of the sensor, which is moreover liable to measure a magnetic field of a conductor situated outside the sensor.

### SUMMARY

The invention therefore aims to resolve the aforementioned disadvantages of the prior art by proposing a new electrical component comprising a winding with a high turns density and a precise arrangement that is simple to manufacture and to integrate into an electrical circuit while being immune to external magnetic fields.

To this end, the invention concerns an electrical component, comprising:
an armature formed of a material comprising a polymer plastic material and an organometallic additive, the armature delimiting a central opening that passes through the armature along a main axis, a printed circuit board onto which the armature is fixed, the printed circuit board and the armature being superposed along the main axis, and
an unbranched electrical line that comprises a first connection point, a second connection point and segments in succession from the first connection point to the second connection point in a circulation direction of the electrical line, each segment being carried either by the armature or by the printed circuit board, each segment being connected to the next segment by a respective junction that is part of the electrical line.

According to the invention the armature comprises at least four arms, the at least four arms being distributed in a loop around the central opening, each arm of the armature forming a respective exterior face that is part of the armature and extends parallel to the main axis and each arm carrying only one of the segments of the electrical line, and at least four junctions, each arm being connected to the adjacent arm by one of the junctions.

Furthermore, the printed circuit board comprises at least four branches, the at least four branches being distributed in a loop around the main axis and delimiting a central hole through which the main axis passes, each branch of the printed circuit board carrying only one of the segments of the electrical line.

Furthermore, the first connection point of the electrical line is connected to the first segment of the electrical line in the circulation direction, the first segment being carried by one of the branches of the printed circuit board, and the last segment of the electrical line in the circulation direction is connected to the second connection point, the last segment being carried by an arm of the armature.

Finally, the electrical component comprises contact pads carried by the armature and each disposed at one of the junctions of the armature and each junction between two consecutive segments of the electrical line, one of which two consecutive segments is carried by an arm of the armature and the other of the two consecutive segments is carried by a branch of the printed circuit board, is formed by one of the contact pads.

Thanks to the invention, the electrical line is divided between the arms of the armature and the branches of the printed circuit board, which confers good performance on the electrical component and in particular good immunity to magnetic fields. Furthermore, this arrangement is simple to manufacture thanks to the contact pads that provide the continuity of the electrical line between the armature and the printed circuit board.

Furthermore, the armature is a plastronic component, which enables the segments of the electrical line formed on the armature to benefit from a high turns density and precise placement, thus improving the performance of the electrical component.

According to advantageous but not obligatory aspects of the invention, this electrical component incorporates one or more of the following features, separately or in all technically admissible combinations:
The contact pads are grouped in pairs, a junction of the armature carrying either a pair of contact pads or no contact pads.
The electrical component comprises four pairs of contact pads and the segments of the electrical line alternate in the circulation direction between a segment carried by a branch of the printed circuit board and a segment carried by an arm of the armature.
The electrical component comprises at least two pairs of contact pads and the segments of the electrical line alternate in the circulation direction between two consecutive segments each carried by a branch of the printed circuit board and two consecutive segments each carried by an arm of the armature.
The electrical component comprises at least one pair of contact pads and the segments of the electrical line alternate in the circulation direction between four consecutive segments each carried by a branch of the printed circuit board and four consecutive segments each carried by an arm of the armature.
The electrical component comprises an auxiliary electrical line carried by the printed circuit board and the auxiliary electrical line is connected to the electrical line between the fourth segment and the fifth segment of the electrical line.
The armature is fixed onto the printed circuit board by means of the contact pads.
Each segment of the electrical line carried by an arm of the armature traces out turns wound around said arm of the armature.
A minimal distance separating two adjacent turns of a segment of the electrical line carried by an arm of the armature as measured on the plane exterior face of said arm of the armature perpendicular to the main axis is less than 400 μm, preferably less than 250 μm.
A first portion of the armature and a second portion of the armature are defined, each portion of the armature being delimited between a first radial plane passing through the main axis and a second radial plane passing through the main axis and offset from the first radial plane, an offset angle between the first radial plane and the second radial plane being identical for the first portion of the armature and for the second portion of the armature. A cumulative area of the turns in the first portion of the armature differs from a cumulative area of the turns in the second portion of the armature by less than 5%.
The central opening of the armature is in the shape of a right cylinder.
The electrical component is a Rogowski type sensor.

In another aspect, the invention also concerns a method for manufacturing an electrical component as referred to hereinabove, the method of manufacture comprising:
preparing the armature, comprising successively:
procuring or producing the armature;
laser etching of the armature to etch at least one starter track tracing out the segments of the electrical line carried by the armature and tracing out the contact pads and where the organometallic additive is locally activated;
metallizing each starter track with a conductive metal to form the segments of the electrical line carried by the armature and to form the contact pads directly on the surface of the armature;
procuring or producing the printed circuit board;
positioning the armature on the printed circuit board; and
soldering the contact pads onto the printed circuit board.

The contact pads are advantageously soldered onto the printed circuit board using a convection remelting oven in which the electrical component is placed.

This method of manufacture has the same advantages as those mentioned hereinabove on the subject of the electrical component according to the invention.

### BRIEF DESCRIPTION OF DRAWINGS

The invention will be better understood and other advantages thereof will become more clearly apparent in the light of the following description of one embodiment of an electrical component and one method for manufacturing such an electrical component given by way of example only and with reference to the appended drawings, in which:

FIG. 1 is an exploded perspective view of an electrical component conforming to a first embodiment of the invention.

FIG. 2 is a view from below of a part of the electrical component from FIG. 1.

FIG. 3 is a functional schematic representing the electrical component from FIG. 1.

FIG. 4 is a functional schematic representing an electrical component conforming to a second embodiment of the invention.

FIG. 5 is a functional schematic representing an electrical component conforming to a third embodiment of the invention.

### DETAILED DESCRIPTION

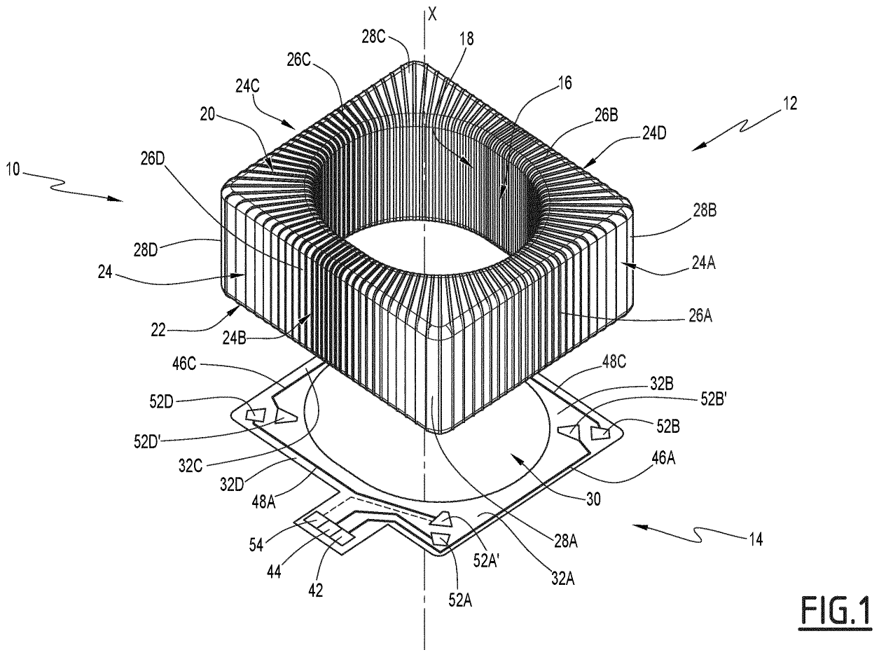

An electrical component 10 in accordance with a first embodiment of the invention is represented in FIGS. 1 to 3. The electrical component 10 comprises an armature 12 and a printed circuit board 14 on which the armature 12 is mounted.

A reference axis X is a main axis of the electrical component 10. The printed circuit board 14 is plane and extends in a plane perpendicular to the main axis X.

The armature 12 preferably consists of a single one-piece part, that is to say a monolithic part, made entirely of the same material.

The material constituting the armature 12 comprises a polymer plastic material, preferably a thermoplastic resin, for example polycarbonate (PC), that is relatively easy to form by injection molding, or liquid crystal polymer (LCP), which is particularly heat resistant. The material also comprises an organometallic additive integrated into the polymer plastic material that is distributed at least in the skin of the armature, or even also in the core. In a non-activated state the organometallic additive is electrically non-conductive. The armature 12 is therefore electrically non-conductive and amagnetic with the possible exception of any activated part of the organometallic additive, as discussed hereinafter.

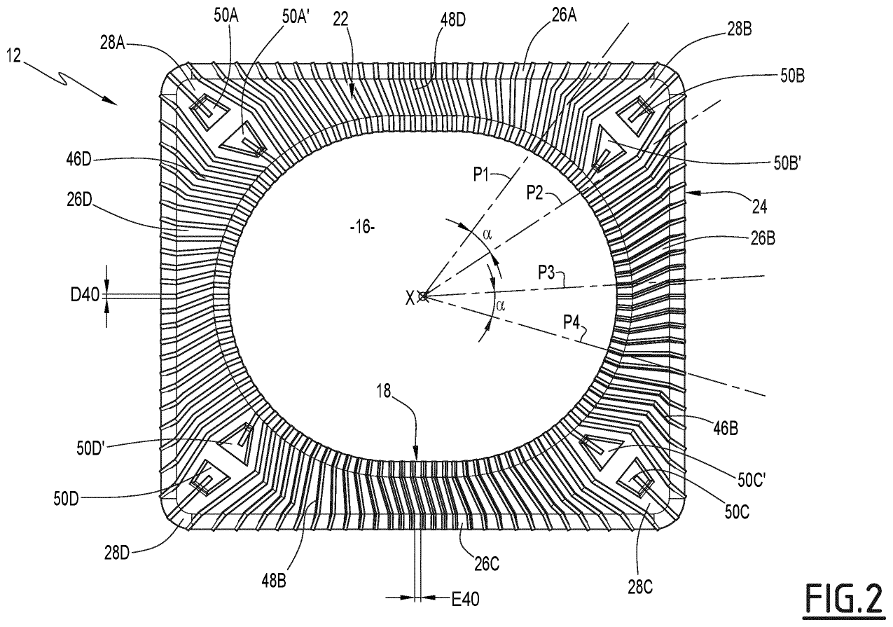

As FIGS. 1 and 2 show, in structural terms the armature 12 has a closed loop general shape around the main axis X or more generally an annular shape, delimiting at its center a central through-opening 16 through which the main axis X passes. The central opening 16 extends along the main axis X so that the central opening is in the form of a circular or non-circular right cylinder. In this example, a section of the central opening 16 perpendicular to the main axis X is of oblong shape. In a variant that is not represented the section of the opening 16 has some other shape, such as a circular or elliptical shape. The central opening 16 delimits an interior face 18 of the armature 12.

In the example of FIGS. 1 and 2 the armature 12 has a rectangular parallelepiped shape including an upper face 20 and a lower face 22 each perpendicular to the main axis X. The opening 16 therefore connects the upper face 20 to the lower face 22, that is to say the interior face 18 of the armature extends from the upper face to the lower face. The armature 12 also has an exterior face 24 that connects the upper face to the lower face and extends parallel to the main axis X. The exterior face 24, the upper face 20 and the lower face 22 therefore define a rectangular parallelepipedal volume through which the central opening 16 passes. In a variant of the invention that is not represented the armature does not have a rectangular parallelepiped shape but a right prismatic shape.

The armature 12 measures for example approximately 25 mm by 25 mm in a plane perpendicular to the axis X and approximately 5 mm along the axis X. More generally, the component described here advantageously has a length between 10 mm and 100 mm, a width between 10 mm and 100 mm, and a height between 2 mm and 40 mm.

In this example, the armature 12 having a rectangular parallelepiped shape, the armature comprises four arms 26A, 26B, 26C and 26D connected to one another in pairs, that is to say two by two, by four junctions 28A, 28B, 28C and 28D, the junctions forming corners of the armature 12. Thus the exterior face 24 of the armature is formed by an exterior face of each arm 26A, 26B, 26C and 26D, that is to say each arm has a respective exterior face 24A, 24B, 24C et 24D. The exterior faces 24A, 24B, 24C and 24D of the four arms 26A, 26B, 26C and 26D are plane and parallel to the axis X. Here two exterior faces of two adjacent arms are perpendicular to one another.

In a variant of the invention that is not represented the armature 12 has some other shape, for example a prismatic shape the base of which is a trapezium or a square. Whatever the shape of the armature 12 it has four arms.

The printed circuit board 14 and the armature 12 are superposed along the axis X so that the lower face 22 of the armature faces the printed circuit board. Furthermore, the printed circuit board includes a central hole 30 through which the axis X passes. In practise the central hole 30 and the central opening 16 are aligned along the axis X.

Furthermore, the printed circuit board 14 comprises four branches 32A, 32B, 32C and 32D that extend in a loop around the axis X. Each branch of the printed circuit board 14 is advantageously aligned with one of the arms of the armature 12 along the axis X.

The electrical component 10 preferably constitutes a current sensor.

The intensity of the current in a conductor extending essentially along the axis X through the loop formed by the four arms 26A, 26B, 26C and 26D of the armature 12 on passing through the opening 16 and passing through the loop formed by the four branches 32A, 32B, 32C and 32D of the printed circuit board 14 in passing through the hole 30 can be determined thanks to the electrical component 10, a voltage being induced at the terminals of the electrical component as a function of the magnetic flux passing through said opening 16 and said hole 30 along the axis X. Furthermore, the thickness of the printed circuit board 14 being small compared to the thickness of the armature 12, in the remainder of the description the magnetic flux passing through the central opening 16 and the central hole 30 are assimilated to the magnetic flux passing only through the central opening 16.

This component is preferably of Rogowski sensor type and the voltage induced reflects the value of the variation of the current passing through the opening 16.

The electrical component 10 is intended to be connected to sensor electronics, not represented, including conditioning electronics taking for example the form of an integrator circuit. In practise the sensor electronics are either connected to the printed circuit board 14 or mounted directly on the printed circuit board.

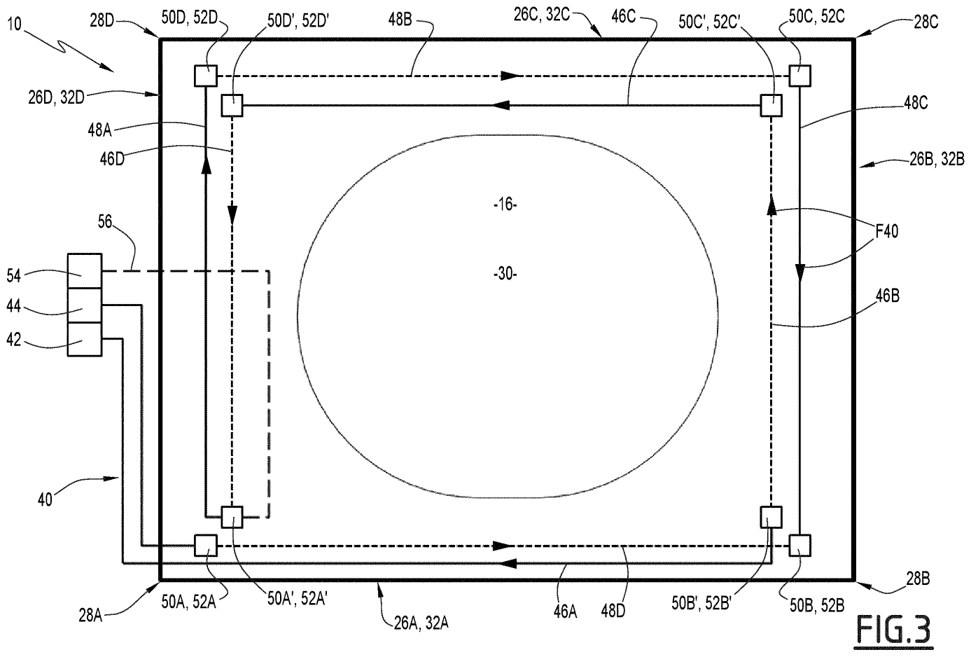

In practise, especially when it is of the Rogowski sensor type, the electronic component 10 comprises an unbranched electrical line 40 that comprises a first connection point 42, a second connection point 44 and successive segments from the first connection point to the second connection point in a circulation direction F40 of the electrical line. The electrical line 40 is represented schematically in FIG. 3. As represented in the figures the first and second connection points are preferably carried by the printed circuit board 14. In the remainder of the description the terms “upstream” and “downstream” are to be understood relative to the circulation direction F40 of the electrical line. Furthermore, it is to be noted that the circulation direction described here is chosen arbitrarily and could equally well be considered as instead going from the second connection point to the first connection point.

Here the first connection point 42 and the second connection point 44 therefore respectively form an input terminal and an output terminal of the electrical line 40 and in the variant the first connection point and the second connection point respectively form an output terminal and an input terminal of the electrical line.

The electrical line 40 extends over the four arms of the armature 12 and over the four branches of the printed circuit board 14. Furthermore, each arm of the armature carries only one segment of the electrical line and each branch of the printed circuit board carries only one segment of the electrical line. The electrical line 40 therefore includes eight segments, that is to say four segments on the arms of the armature and four segments on the branches of the printed circuit board. In FIG. 3 can be seen the segments of the electrical line 40 carried by the printed circuit board 14, each represented by a solid line, distinguished from the segments of the electrical line carried by the armature 12, each represented by a dashed line with short dashes.

The electrical line 40 is an electrical conductor so that when a conductor is placed in the openings 16 and 30 of the electrical component 10 this conductor induces a voltage in the electrical line, this voltage depending on the magnetic flux passing through the openings 16 and 30, being more precisely proportional to the value of the variation of the current in said conductor. A voltage is therefore induced at the terminals of the electrical line 40, that is to say between the first connection point 42 and the second connection point 44. The electrical component 10 then behaves as a sensor measuring a change in the current in a conductor placed in the openings 16, The armature being made of a polymer plastic material and carrying a conductive track formed by the electrical line 40, it can be described as a plastronic component.

As can be seen better in FIGS. 1 and 2 each segment of the electrical line 40 carried by one of the arms 26A-26D of the armature 12 traces out turns around said arm of the armature, that is to say propagating all around the arm, along the interior face 18, the upper face 20, the lower face 22 and the exterior face 24 of the arm. Each of these segments therefore forms a winding. Furthermore, on each arm of the armature the turns of the electrical line are present along all of the length of the arm, that is to say they extend between the two junctions delimiting that arm. In other words, the electrical line is wound in a spiral around the arms of the armature. The electrical line therefore extends in three dimensions over the armature 12.

Conversely, each segment of the electrical line being carried by one of the branches 32A-32D of the printed circuit board 14 extends in an essentially rectilinear manner over all the length of said branch, that is to say without forming any turn or loop. The electrical line therefore extends in two dimensions over the armature 12, that is to say is flat.

It is therefore clear that the length of a segment of the electrical line 40 carried by one of the arms of the armature is much greater than the length of a segment of the electrical line carried by one of the branches of the printed circuit board.

Being carried by the arms of the armature and by the branches of the printed circuit board, the electrical line 40 extends all around the axis X.

Of the eight segments of the electrical line 40, the first four segments 46A, 46B, 46C and 46D are distinguished from the last four segments 48A, 48B, 48C and 48D. The four first segments 46A to 46D extend around the axis X in a first direction, for example in the counterclockwise direction as seen in FIG. 3, so as to form a first loop entirely surrounding the axis X, and the last four segments 48A to 48D extend around the axis X in a second direction opposite the first direction, for example in the clockwise direction as seen in FIG. 3, so as to form a second loop entirely surrounding the axis X. In other words, the electrical line 40 includes two loops which entirely surround the axis X in opposite directions. In the usual way the first loop formed by the segments 46A-46D is known as the “go loop” and the second loop formed by the second segments 48A-48D is known as the “return loop”.

Thus the two loops formed by the segments 46A to 46D and 48A to 48D of the electrical line 40 entirely surround the axis X in a first direction and then in a second direction and the first connection point 42 and the second connection point 44 are therefore situated near one another, that is to say at the same level, in a circumferential direction around the axis X. In particular, the first connection point 42 and the second connection point 44 are carried by the same branch of the printed circuit board 14, in this example by the branch 32B.

The electrical line 40 therefore comprises distinct segments 46A-46D and 48A-48D that are connected to one another by junctions of the electrical line. In this example these junctions are formed by contact pads situated on the lower face 22 of the armature 12. In practise in the first embodiment the electrical line 40 comprises eight contact pads that are carried by the junctions 28A to 28D of the armature 12 so that each junction of the armature carries two contact pads. Thus of the contact pads of the electrical line two contact pads 50A and 50A′ disposed at the level of the junction 28A are distinguished from two contact pads 50B and 50B′ disposed at the level of the junction 28B, and two contact pads 50C and 50C′ disposed at the level of the junction 28C are distinguished from two contact pads 50D and 50D′ disposed at the level of the junction 28D. In other words, the contact pads are grouped in pairs and each junction of the armature comprises one pair of contact pads.

Each segment 46A-46D and 48A-48D of the electrical line 40 is therefore connected to the next segment of the electrical line in the circulation direction F40 by a junction of the electrical line formed by one of the contact pads 50A, 50A′, 50B, 50B′, 50C, 50C′, 50D, 50D′, the first segment 46A being also connected to the first connection point 42, which is situated upstream of the first segment in the circulation direction, and the last segment 48D being connected to the second connection point 44, which is situated downstream of the last segment in the circulation direction.

As can be seen better in FIG. 3, in the first embodiment the electrical line 40 is divided between the armature 12 and the printed circuit board 14 so that, of two consecutive segments of the electrical line a first is carried by an arm of the armature and a second is carried by a branch of the printed circuit board. Furthermore, in this example the first segment 46A is carried by the printed circuit board. Thus in this example the segments 46A, 46C, 48A and 48C are carried by the circuit printed board 14, respectively by the branches 32A, 32C, 32D and 32B of the printed circuit board. Furthermore, the segments 46B, 46D, 48B and 48D are carried by the armature 12, by the respective arms 26B, 26D, 26C and 26A of the armature.

It is then clear that the junctions of the electrical line 40 formed by the contact pads 50A, 50A′, 50B, 50B′, 50C, 50C′, 50D, 50D′ enable a junction to be made between two consecutive segments of the electrical line, one of the two consecutive segments of which is carried by an arm of the armature and the other of the two consecutive segments of which is carried by a branch of the printed circuit board. In other words, the contact pads make it possible to ensure continuity of the electrical line 40 between the printed circuit board and the armature.

Note that, among the contact pads, the contact pad 50A′ enables an electrical connection to be made between the last segment 46D of the first loop and the first segment 48A of the first loop. The electrical line 40 therefore changes direction at the level of the contact pad 50A′.

It is therefore clear that the go loop and the return loop are open loops the two ends of which are situated at the level of the contact pads 50A, 50A′, that is to say at the level of the junction 28A of the armature 12. The electrical component 10 therefore features a low level of crosstalk, or good immunity, that is to say that the electrical component 10 detects a conductor passing through the opening 16 and 30 effectively but is relatively little disturbed by a conductor situated outside the openings 16 and 30, that is to say outside the electrical component. Indeed, the area liable to capture exterior fields is here reduced to the area of the arms of the armature 12 and the branches of the printed circuit board 14 of the electrical component 10, in contrast to an electrical component including no go-return conductors in which the area liable to capture exterior fields corresponds to the total area of the component, including openings.

Furthermore, note that the first segment 46A is connected to the first connection point 42 with no contact pad disposed between the first connection point and the first segment. The absence of any contact pad between the first connection point and the first segment is possible because the first connection point and the first segment are both formed on the printed circuit board and can therefore be directly connected by an electrical track on the printed circuit board. Here an unbranched electrical track therefore extends between the first connection point and the first segment 46A, enabling the first connection point to be located away from the branch 32A of the printed circuit board. In a variant of the invention that is not represented the first connection point is disposed directly at the upstream end of the first segment 46A.

Note that the last segment 48D is connected to the second connection point 44 via the contact pad 50A. This contact pad is needed to make this connection because the last segment 48D is carried by the arm 26A of the armature 12 whereas the second connection point 44 is formed on the printed circuit board 14. Thus the contact pad 50A does not make a connection between two consecutive segments of the electrical line 40. The contact pad 50A is also termed a connection pad. Here an unbranched electrical track extends between the second connection point and the contact pad 50A, enabling the second connection point to be farther from the last segment 48D. In a variant of the invention that is not represented the second connection point is formed directly by the contact pad 50A.

The arrangement of the electrical line 40 with segments successively carried by the armature 12 and by the printed circuit board 14 is particularly advantageous for improving the crosstalk of the electrical component 10, that is to say its immunity to exterior interference. Indeed, thanks to this arrangement the length of the first loop formed by the segments 46A-46D is substantially equal to the length of the second loop formed by the segments 48A-48D.

The electrical component 10 advantageously also comprises a third connection point 54 and an auxiliary electrical line 56 that are carried by the printed circuit board 14. As can be seen better in FIG. 3 the auxiliary electrical line 56 is connected on the one hand to the third connection point 54 and on the other hand to the contact pad 50A′, that is to say to the junction between the last segment 46D of the first loop of the electrical line 40 and the first segment 48A of the second loop. In a variant that is not represented the auxiliary electrical line 56 is not connected to the contact pad 50A′ but directly to the segment 46D or the segment 48A of the electrical line 40. In other words the auxiliary electrical line is connected to the electrical line between the fourth and fifth segments of the electrical line, that is to say at or close to the center of the electrical line. The third connection point 54 is preferably a ground point of the printed circuit board 14 that is not represented, that is to say the connection point the voltage at which is equal to 0 V. The presence of the third connection point 54 and the auxiliary electrical line 56 is particularly advantageous because when the electrical component 10 is used as a Rogowski sensor it enables differential measurement to enable improvement of the measurement accuracy of the electrical component and to prevent capacitive interaction phenomena between the electrical line 40 and the conductor passing through the openings 16, 30. In particular the measurement accuracy of the sensor is improved because conversion of the analog signal coming from the sensor into a digital signal is more precise and the analog signal can then be centered with respect to a zero value, which makes it possible to limit signal saturation phenomena. The positioning of the auxiliary electrical line 56 described here is particularly advantageous because, being connected to the center of the electrical line 40, the performance of the electrical component 10 is optimized.

The combined use of the plastronic armature 12 on which some of the segments of the electrical line 40 are formed and the printed circuit board 14 on which other segments of the electrical line 40 are formed is particularly advantageous in that it makes it possible to obtain a go loop and a return loop in which the dimensions of the segments carried by the armature are maximized, thus enabling the formation of a particularly compact and high-performance Rogowski type current sensor, the performance of which is therefore optimized, with a high gain and a high accuracy, without suffering saturation.

Another advantage of the invention is to facilitate integrating the electrical component 10 into an electrical circuit because the printed circuit board 14 can easily be fixed, for example soldered, to another printed circuit board or connected to another printed circuit board by electrical wires.

Furthermore, the electrical component may also be integrated directly into an electrical circuit by integrating the various components carried by the printed circuit board 14 on another printed circuit board.

The electrical component 10 from FIGS. 1 to 3 is obtained with the aid of the method of manufacture defined hereinafter.

The method of manufacture essentially comprises successively procurement or manufacture of the armature 12 followed by laser etching of the armature 12 followed by chemical treatment of the armature 12 including metallization to form the electrical line 40 followed by assembly of the armature 12 onto the printed circuit board 14.

The manufacture of the armature 12 preferably comprises molding the armature by injection of material into a mold when the material is in a viscous state. The mold is configured to shape all parts of the armature 12 in a single molding operation.

Once the armature 12 has been manufactured there follows laser etching of the armature. In particular, on all the faces 18, 20, 22 and 24 of the armature and on the four arms 26A-26D of the armature there is laser etched a starter track that can later serve as a base for forming the segments of the electrical line 40 carried by the armature.

The material of the armature 12 is specifically provided to enable the formation of the starter track by laser etching, for example with the aid of any appropriate laser etching tool. By “laser etching tool” is meant for example an apparatus comprising a source of a laser beam, means for orienting the laser beam, for example a set of mirrors adapted to be oriented, and means for focusing the laser beam, such as a set of lenses.

The local application of the laser radiation to the surface of the material forms the starter track, which can be traced out as required by application of the laser radiation. The laser etching is aimed at forming the starter track on the armature 12 so that the starter track traces out exactly the same line as the segments of the electric line 40 carried by the armature. The starter track is wound in a spiral around the armature 12 in order to form a succession of turns that will constitute the segments 46B, 46D, 48B and 48D of the electrical line 40 at a later stage of the method. These segments therefore form windings. The starter track is distinguished from the rest of the surface of the armature 12 in that it consists of activated portions of the organometallic additive whereas on the rest of the armature the organometallic additive is in a non-activated state. Furthermore, the starter track is distinguished from the rest of the armature 12 in that it forms a groove or at least in that it has a more abrasive surface state.

The organometallic additive is preferably formed by a metal complex comprising a metal, for example copper core which in the non-activated state is connected by a covalent link to the polymer plastic material. This organometallic additive can be activated selectively on the surface of the armature by local and selective application of appropriate laser radiation, for example pulsed infrared laser radiation. To activate the organometallic additive the laser radiation breaks up the complex which frees the metal core only at the location at which the radiation is applied. To be more precise, the laser radiation leads to a reduction of the metal of the complex, the core then having the metallic form, here the metallic copper form. Furthermore, the laser radiation locally heats the surface of the material, which locally increases the roughness of the surface by partial ablation of the polymer plastic material.

Once the laser etching has been effected the armature 12 is preferably cleaned to remove any debris caused by this operation.

The starter track etched in this way is not sufficiently electrically conductive for the electrical component 10 to be able to function. The armature 12 is therefore chemically treated to cause this starter track to grow.

The chemical treatment consists firstly in metallization of the starter track to form the segments 46B, 46D, 48B and 48D of the electrical line 40 directly on the surface of the armature 12. This metallization leads to growth of the starter track whereas the rest of the surface of the armature 12 remains electrically insulative.

By “metallization” is meant for example autocatalytic metallization. The armature carrying the starter track is immersed in a solution containing ions of the metal of which the conductive tracks are to be formed, for example copper. For example the solution comprises a metal salt containing the metal ions, here the copper ions, and a reducing agent for reducing the metal ions. By a redox reaction the metal of the metal ions is deposited only on the starter track without being deposited on the rest of the surface of the armature 1, the starter track constituting a catalyst for the redox reaction. The layer of metal deposited by this process constitutes a catalyst for the redox deposition of more metal. This is therefore what grows the segments 46B, 46D, 48B and 48D of the electrical line 40 by means of the metallization. Mechanically speaking the segments of the electrical line formed in this way are strongly adherent to the polymer plastic material because they are mechanically anchored on asperities caused by the abrasive character of the surface of the armature 12 because of the laser etching.

Once the segments 46B, 46D, 48B and 48D of the electrical line 40 have been formed by metallization the chemical treatments preferably include the deposition of finishing layers to protect these segments. To this end an electroless nickel immersion gold (ENIG) type process is used for example.

To this end a nickel-phosphate layer is first applied by autocatalytic metallization on the free face of the conductive track, that is to say the face opposite the surface of the armature 12. This auto-catalytic metallization is advantageously effected after the copper conductive tracks have been activated using palladium. An external layer of gold is then applied, for example by chemical displacement. The layer of gold prevents oxidation of the covered conductive tracks while the nickel-phosphate layer prevents migration of the gold to the copper.

The chemical treatment to form the segments 46B, 46D, 48B and 48D of the electrical line 40 completes the manufacture of the armature 12.

In parallel with the manufacture of the armature 12, the printed circuit board 14 is manufactured or procured by methods known from elsewhere, so as to form on the printed circuit board the segments 46A, 46C, 48A and 48C of the electrical line 40 and the first, second and where applicable third connection points 42, 44 and 54.

After manufacturing the armature 12 and the printed circuit board 14 the armature and the printed circuit board are assembled to one another to form the electrical component 10. This assembly is effected in two stages.

In a first stage the armature is positioned on the printed circuit board so as to bring the contact pads 50A, 50A′, 50B, 50B′, 50C, 50C′, 50D, 50D′ into contact with the ends of the segments 46A, 46C, 48A and 48C of the electrical line 40 and to align along the axis X the opening 16 in the armature and the opening 30 in the printed circuit board.

In a second stage the armature is fixed to the printed circuit board by soldering the contact pads 50A, 50A′, 50B, 50B′, 50C, 50C′, 50D, 50D′ to the printed circuit board and more specifically to the ends of the segments 46A, 46C, 48A and 48C of the electrical line 40. Thanks to this fixing method the contact pads advantageously retain the armature 12 on the printed circuit board 14 mechanically as well as producing the electrical continuity of the electrical line 40.

This step completes the electrical component 10.

In a particularly advantageous manner the contact pads are soldered onto the printed circuit board using a convection remelting oven in which the electrical component 10 is placed. This convection remelting enables good mechanical retention of the armature 12 on the printed circuit board to be achieved, thereby limiting the risk of the electrical component 10 being degraded, for example the risk of the armature 12 being torn off, whilst simultaneously making a good electrical connection between the contact pads and the segments of the electrical line carried by the printed circuit board.

Furthermore, soldering makes it possible to limit the stresses applied to the printed circuit board and therefore to limit the risk of unsticking or cracking of the segments of the electrical line 10 carried by the printed circuit board.

Thanks to this method of manufacture, and in particular thanks to the convection remelting step, the manufacture of the electrical component 10 is entirely automated. In particular, the armature 12 can be positioned on and then fixed to the printed circuit board 14 in an entirely automated manner, facilitating the manufacture of the electrical component 10 and guaranteeing highly reliable positioning of the armature 12 on the printed circuit board 14.

As can be seen in FIG. 1, in this example the printed circuit board 14 includes contact zones 52A, 52A′, 52B, 52B′, 52C, 52C′, 52D, 52D′ that are part of the electrical line 40 and are respectively disposed along the axis X facing the contact pads 50A, 50A′, 50B, 50B′, 50C, 50C′, 50D, 50D′. In practise the contact zones are provided to widen the segments of the electrical line formed on the printed circuit board at the level of their ends and to facilitate the connection between these segments and the contact pads. In a variant of the invention that is not represented the printed circuit board does not include such zones.

The method of manufacture as described hereinabove is particularly advantageous for obtaining an electrical component 10 with a high turns density, the turns of which are moreover of large size. The positioning of the turns is moreover particularly well controlled, which assures optimal performance of the electrical component.

Furthermore, thanks to the method of manufacturing the armature 12 the width of the electrical line 40 carried by the armature 12 measured in the same manner and denoted D 40 is advantageously less than 400 μm or even less than 200 μm. The width D40 is preferably 100 μm. The electrical line 40 being very thin, it is represented with a thickness greater than its real thickness in FIGS. 1 and 2. In other words, the electrical line is not represented to scale in FIGS. 1 and 2.

Furthermore, thanks to the method of manufacturing the armature 12 the minimal distance, denoted E40, separating two adjacent turns of a segment of the electrical line 40 by an arm 26A-46D of the armature 12 as measured on the exterior face 24A-24D of that arm perpendicular to the axis X is less than 400 μm, preferably less than 200 μm. The minimal distance E40 is preferably equal to 100 μm.

A very high turns density can therefore be obtained on the armature 12, for example several turns per millimeter, as well as precise tracking of the conductive track 40. Furthermore, the section of the arms of the armature, and thus the section of the turns wound around the arms of the armature, can be made very large by designing the armature 12 to have any required shape. Indeed, at the level of the arms of the armature, the conductive track 40 being formed directly on the surface of the armature, it is the shape of the section of the armature 12 that determines the geometry of the cross section of each turn and therefore the envelope of the segments of the conductive track carried by the armature. In particular, the cross section of each turn corresponds to the exterior contour of the armature 12 as seen in the plane of the turn. This results here in each turn being of rectangular shape, given the shape of the armature 12.

The section of the arms 26A-26D of the armature can have a width as measured perpendicularly to the axis X and to the exterior face 24 or otherwise a characteristic magnitude such as the length of a diagonal that is greater than 1 mm, for example 5 mm, or even greater than 5 mm. Each turn can therefore have a circumference of at least approximately 4 mm. For example, the armature can carry on its four arms around one hundred turns. The cumulative length of the segments of the electrical line 40 carried by the armature 12 can for example be between 400 and 8 000 mm. In comparison, the cumulative length of the segments of the electrical line carried by the printed circuit board 14 can be between 10 mm and 400 mm.

The large size and the density of turns that can be obtained thanks to the electrical component of the invention make it possible to obtain a signal/noise ratio higher than that of known sensors. In other words, the gain and the accuracy of the electrical component are improved relative to known sensors.

Furthermore, and as can be seen better in FIG. 2, the distance separating two adjacent turns of a segment of the electrical line 40 carried by an arm 26A-46D of the armature 12 can vary along said arm. In other words, the pitch of the winding formed by the turns carried by an arm is variable and the minimal value of that pitch is equal to E40. Indeed, the turns are tighter at the level of the center of the arms 26A-26D than near the junctions 28A-28D. Furthermore, since the armature 12 is of parallelepipedal shape the turns situated at the junctions 28A-28D of the armature are larger than the turns situated at the centers of the arms 26A-26D of the armature.

The electrical line 40 is advantageously designed so that the variability of the separation of the turns and the variability of the size of the turns cooperate so that the flux captured by a portion of the segments of the electrical line 40 carried by the armature is globally constant whatever the portion of the electrical line concerned, which enables good crosstalk to be obtained despite the rectangular shape of the electrical component 10. The performance of the electrical component 10 as a sensor is therefore independent of the orientation of the electrical component around the axis X.

For example, a first portion of the armature and a second portion of the armature are defined. The first portion of the armature is delimited between a first radial plane P1 passing through the axis X and a second radial plane P2 passing through the axis X and offset relative to the first radial plane at an angle a. The second portion of the armature is delimited between a third radial plane P3 passing through the axis X and a fourth radial plane P4 passes X and offset from the third radial plane at an angle a. The offset angle a is identical for the first portion of the armature and the second portion of the armature. Note that here the first portion of the armature is centered around the junction 28B and the second portion of the armature is situated at the level of the arm 26B of the armature. In practise, to obtain good crosstalk the separation of turns is such that a cumulative area of the turns contained in the first portion of the armature differs from a cumulative area of the turns included in the second portion of the armature by at least 5%, preferably by at least 2%, whatever the angle a, for an angle a at least equal to 10°. The shorter this distance, the greater the immunity of the electrical component 10 and the more the performance of the electrical component is independent of the position of the conductor in the openings 16 and 30.

Furthermore, the fact that the turns of the electrical line 40 are farther apart at the level of the junctions 28A-28D is particularly advantageous in facilitating the manufacture of the armature 12 by facilitating the positioning of the contact pads 50A-50D and 50A′-50D′. In particular, and as can be seen better in FIG. 2, the turns are locally offset at the level of the interior face 22 of the armature 12 to accommodate the presence of the contact pads. The result of this is that the positioning of the contact pads at the level of the junctions 28A-28D of the armature does not significantly degrade the crosstalk of the electrical component 10.

Furthermore, the electrical component 10 not comprising any ferromagnetic part, it is not subjected to interference generated by magnetic fields external to the electrical component, that is to say is not sensitive to an external magnetic field.

In a variant of the invention that is not represented the electrical component 10 does not form a Rogowski type sensor but some other type of electrical component, such as an antenna for example, such as a planar or non-planar antenna.

In the example described hereinabove the armature 12 and the printed circuit board 14 respectively have four arms and four branches. The resulting rectangular parallelepiped shape of the electrical component 10 is particularly advantageous in improving the compactness of the electrical component and facilitating its integration into an electronic circuit. In a variant of the invention that is not represented the armature 12 and the printed circuit board 14 each comprise a different number of arms and branches, for example five, six or eight arms and branches. A number of arms and branches greater than four improves the arrangement of the electrical line 40 and therefore improves the performance of the electrical component.

In the example described hereinabove the electrical line 40 comprises two loops connected in series, namely a go loop and a return loop, each making a complete turn around the axis X, and carried by the armature 12 and the printed circuit board 14. In a variant of the invention that is not represented the electrical line 40 comprises four half-loops connected in series, namely a first go half-loop making a half-turn around the axis X in a first direction relative to the first and second connection points 42, 44, then a first return half-loop, then a second go half-loop making a half-turn around the axis X in a second direction opposite the first direction, then a second return half-loop. Note that in such a variant the electrical line 40 still forms a go loop and a return loop but the connection points 42, 44 are not disposed at one end of those loops but rather at the center of those loops.

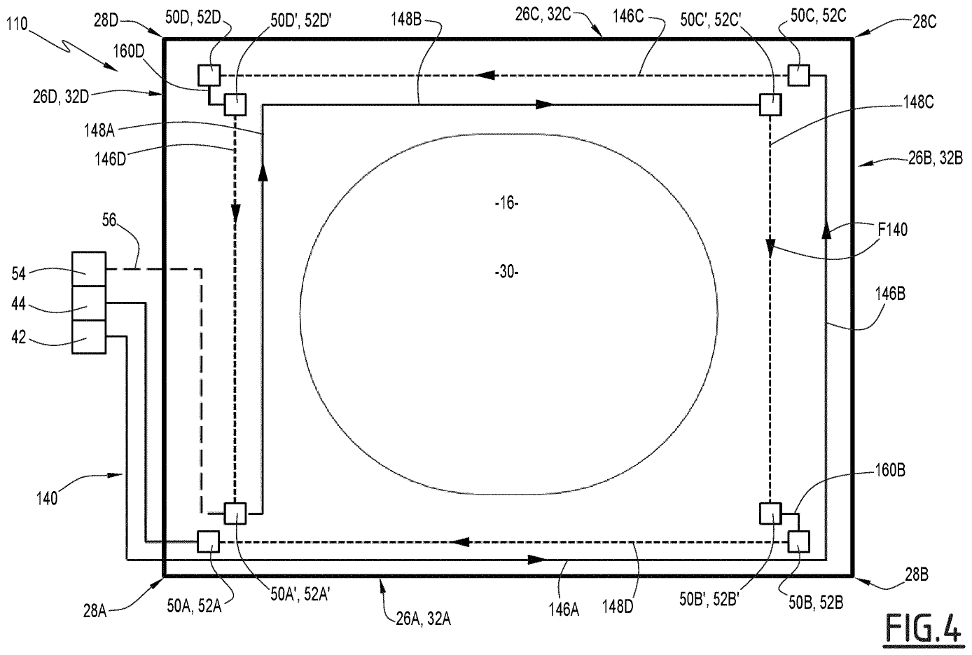

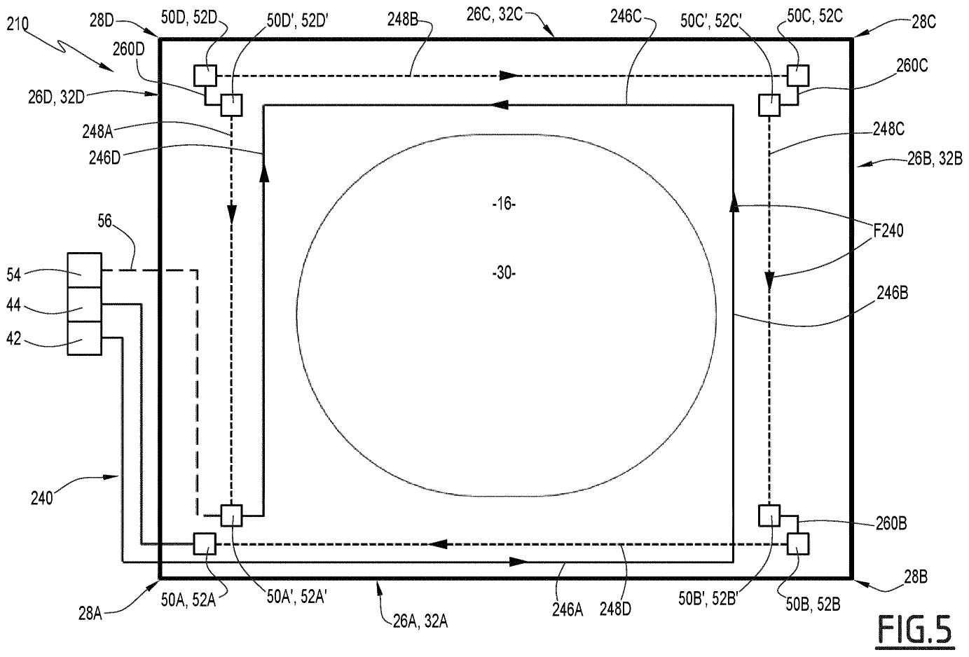

A second embodiment 110 and a third embodiment 210 of the electrical component are respectively represented in FIG. 4 and in FIG. 5. In the second and third embodiments elements identical to those of the first embodiment bear the same references and elements analogous to those of the first embodiment bear the same references respectively increased by 100 or 200. The electronic components of the second and third embodiments and their method of manufacture are identical to those of the first embodiment from FIGS. 1 to 3 except for the differences mentioned hereinafter. There are mainly described hereinafter the differences between the first, second and third embodiments.

Furthermore, if a component is mentioned in the description of the second or third embodiment without being represented in FIG. 4 or FIG. 5 it corresponds to the same element in the first embodiment represented in FIGS. 1 to 3.

In the second embodiment the armature 12 and the printed circuit board 14 are identical to those of the first embodiment. Differing in this respect from the first embodiment, the segments of the electrical line 140 do not alternate between a segment carried by the printed circuit board and a segment carried by the armature but rather between two segments carried by the printed circuit board and two segments carried by the armature. In the circulation direction F140 of the electrical line 140 there can therefore be distinguished, in this order: two segments 146A, 146B carried by the printed circuit board, then two segments 146C, 146D carried by the armature, these four segments forming the first loop of the electrical line, then two segments 148A, 148B carried by the printed circuit board, then two segments 148C, 148D carried by the armature, these four segments forming the second loop of the electrical line.

In the second embodiment, as in the first embodiment, the armature 12 includes eight contact pads. However, as FIG. 4 shows, some contact pads are not provided to make a connection between a segment of the electrical line carried by the armature and a segment carried by the printed circuit board, but to the contrary to make a connection between two consecutive segments of the electrical line carried by the armature. Thus in this example the segments 146C and 146D of the electrical line are connected to one another by the contacts pads 50D, 50D′ and the segments 148C and 148D are connected to one another by the contact pads 50B, 50B′. In other words, in the second embodiment the contact pads 50B, 50B′, 50D and 50D′ do not divide the electrical line 40 between the armature 12 and the printed circuit board 14 but rather mechanically retain the armature on the printed circuit board. These contact pads are alternatively known as connection pads.

In the FIG. 4 example the contact pads 50D and 50D′ are connected to one another by a pin 160D formed on the printed circuit board 14. In the same manner the contact pads 50B and 50B′ are also connected to one another by a pin 160B formed on the printed circuit board. In a variant of the invention that is not represented the electrical line 140 does not comprise any connection pads 50B, 50B′, 50D, 50D′ and the segments 146C and 146D on the one hand and the segments 148C and 148D on the other hand are connected to one another directly by a pin formed on the surface of the armature 12. The turns formed on the armature 12 are alternatively uninterrupted between the segments 146C and 146D on the one hand and between the segments 148C and 148D on the other hand. In other words, in such a variant some of the junctions of the electrical line are not formed by contact pads and merely formalize the passage between two consecutive segments formed on the surface of the armature 12, not being physically separate from the turns of said two segments. In such a variant complementary means for fixing the armature onto the printed circuit board can be provided.

It is then clear that the junctions of the electrical line between two consecutive segments carried by the printed circuit board 14 and in particular between the segments 146A and 146B on the one hand and the segments 148A and 148B on the other hand are formed by a portion of the conductive track formed on the printed circuit board 14, which is for example elbow-shaped. These junctions therefore formalize only the passage between two consecutive segments formed on the surface of the printed circuit board and are not physically separate from the conductive track.

In the third embodiment the armature 12 and the printed circuit board 14 are identical to those of the first embodiment. Differing in this respect from the first embodiment, the segments of the electrical line 240 do not alternate between a segment carried by the printed circuit board and a segment carried by the armature, but rather between four segments carried by the printed circuit board and four segments carried by the armature. In the circulation direction F240 of the electrical line 240 there are therefore distinguished, in this order: four segments 246A to 246D carried by the printed circuit board, these four segments forming the first loop of the electrical line, then four segments 248A to 248D carried by the armature, these four segments forming the second loop of the electrical line.

In the third embodiment, as in the first embodiment, the armature 12 includes eight contact pads. However, as FIG. 5 shows, some contacts are not designed to provide a connection between a segment of the electrical line carried by the armature and a segment carried by the printed circuit board, but to the contrary are designed to make a connection between two consecutive segments of the electrical line carried by the armature. Thus in this example the segments 248A and 248B are connected to one another by the contact pads 50D, 50D′, the segments 248B and 248C are connected to one another by the contact pads 50C, 50C′, and the segments 248C and 248D are connected to one another by the contact pads 50B, 50B′. In other words, in the second embodiment the contact pads 50B, 50B′, 50C, 50C′, 50D and 50D′ do not divide the electrical line 40 between the armature 12 and the printed circuit board 14 but mechanically retain the armature on the printed circuit board. These contact pads are alternatively known as connection pads.

In a manner analogous to the second embodiment, in the FIG. 5 example the contact pads 50B and 50B′ are connected to one another by a pin 260B formed on the printed circuit board 14, the contact pads 50C and 50C′ are connected to one another by a pin 260C formed on the printed circuit board, and the contact pads 50D and 50D′ are connected to one another by a pin 260D formed on the printed circuit board. In a variant of the invention that is not represented the electrical line 240 does not include connection pads 50B, 50B′, 50C, 50C′, 50D, 50D′ and the segments 248A, 248B, 248C and 248D are connected to one another directly by pins formed on the surface of the armature 12 or the turns formed on the armature 12 are uninterrupted between the segments 248A, 248B, 248C and 248D, that is to say all the turns of the armature 12 are connected to one another. It is then clear that the junctions of the electrical line between two consecutive segments carried by the armature 12 merely formalize the passage between two consecutive segments and are not physically separate from the turns of said consecutive segments. Furthermore, the segments 246A, 246B, 246C and 246D are preferably formed by an uninterrupted track on the printed circuit board 14. In other words, in such a variant some of the junctions of the electrical line are not formed by contact pads. In such a variant, complementary means for fixing the armature onto the printed circuit board can be provided.

It is then clear that the junctions of the electrical line between two consecutive segments carried by the circuit board 14, and notably between the segments 246A 246B, 246C and 246D, are formed by a portion of the conductive track formed on the printed circuit board 14, which is for example elbow-shaped. These junctions therefore merely formalize the passage between two consecutive segments formed on the surface of the printed circuit board and are not physically separate from the conductive track.

Any feature described in the foregoing description for one embodiment or one variant can be used for the other embodiments and variants described in the foregoing description.

1. An electrical component comprising:
an armature formed of a material comprising a polymer plastic material and an organometallic additive, the armature delimiting a central opening that passes through the armature along a main axis,
a printed circuit board onto which the armature is fixed, the printed circuit board and the armature being superposed along the main axis, and
an unbranched electrical line that comprises a first connection point, a second connection point and segments in succession from the first connection point to the second connection point in a circulation direction of the electrical line, each segment being carried either by the armature or by the printed circuit board, each segment being connected to the next segment by a respective junction that is part of the electrical line,
wherein the armature comprises:
at least four arms the at least four arms being distributed in a loop around the central opening, each arm of the armature forming a respective exterior face that is part of the armature and extends parallel to the main axis Xand each arm carrying only one of the segments of the electrical line, and
at least four junctions each arm being connected to the adjacent arm by one of the junctions,
wherein the printed circuit board comprises at least four branches the at least four branches being distributed in a loop around the main axis and delimiting a central hole through which the main axis passes, each branch of the printed circuit board carrying only one of the segments of the electrical line,
wherein:
the first connection point of the electrical line is connected to thea first segment of the electrical line in the circulation direction, the first segment being carried by one of the branches of the printed circuit board, and
a last segment of the electrical line in the circulation direction is connected to the second connection point, the last segment being carried by an arm
of the armature, and wherein:
the electrical component comprises contact pads carried by the armature and each disposed at one of the junctions of the armature, and
each junction between two consecutive segments of the electrical line, one of which two consecutive segments is carried by an arm of the armature and the other of the two consecutive segments is carried by a branch of the printed circuit board, is formed by one of the contact pads.

2. The electrical component of claim 1 wherein the contact pads are grouped in pairs, a junction of the armature carrying either a pair of contact pads or no contact pads.

3. The electrical component of claim 2 wherein the electrical component comprises four pairs of contact pads and the segments of the electrical line alternate in the circulation direction between a segment carried by a branch of the printed circuit board and a segment carried by an arm of the armature.

4. The electrical component of claim 2 wherein the electrical component comprises at least two pairs of contact pads and the segments of the electrical line alternate in the circulation direction between two consecutive segments each carried by a branch of the printed circuit board and two consecutive segments each carried by an arm of the armature.

5. The electrical component of claim 2 wherein the electrical component comprises at least one pair of contact pads and the segments of the electrical line alternate in the circulation direction between four consecutive segments each carried by a branch of the printed circuit board and four consecutive segments each carried by an arm of the armature.

6. The electrical component of claim 1 wherein the electrical component comprises an auxiliary electrical line carried by the printed circuit board and the auxiliary electrical line is connected to the electrical line between thea fourth segment and thea fifth segment of the electrical line.

7. The electrical component of claim 1 wherein the armature is fixed onto the printed circuit board by means of the contact pads.

8. The electrical component of claim 1 wherein each segment of the electrical line carried by an arm of the armature traces out turns wound around said arm of the armature.

9. The electrical component of claim 8 wherein a minimal distance separating two adjacent turns of a segment of the electrical line carried by an arm of the armature as measured on the plane exterior face of said arm of the armature perpendicularly to the main axis is less than 400 μm.

10. The electrical component of claim 8 wherein a first portion of the armature and a second portion of the armature are defined, each portion of the armature being delimited in a first radial plane (P1, passing through the main axis Xand a second radial plane passing through the main axis and offset from the first radial plane, an offset angle between the first radial plane and the second radial plane being identical for the first portion of the armature and for the second portion of the armature, and a cumulative area of the turns in the first portion of the armature differs from a cumulative area of the turns in the second portion of the armature by less than 5%.

11. The electrical component of claim 1 wherein the central opening of the armature is in the shape of a right cylinder.

12. The electrical component of claim 1 wherein the electrical component is a Rogowski type sensor.

13. A method for manufacturing an electrical component, the electrical component comprising:
an armature formed of a material comprising a polymer plastic material and an organometallic additive, the armature delimiting a central opening that passes through the armature along a main axis,
a printed circuit board onto which the armature is fixed, the printed circuit board and the armature being superposed along the main axis, and
an unbranched electrical line that comprises a first connection point, a second connection point and segments in succession from the first connection point to the second connection point in a circulation direction of the electrical line, each segment being carried either by the armature or by the printed circuit board, each segment being connected to the next segment by a respective junction that is part of the electrical line, the method of manufacture comprising:
preparing the armature, comprising successively:
procuring or producing the armature;
laser etching the armature to etch at least one starter track tracing out the segments of the electrical line carried by the armature and tracing out the contact pads carried by the armature and each disposed at one of the junctions of the armature and where said organometallic additive is locally activated;
metallizing each starter track with a conductive metal to form the segments of the electrical line carried by the armature and to form the contact pads directly on the surface of the armature;
procuring or producing the printed circuit board;
positioning the armature on the printed circuit board; and
soldering the contact pads onto the printed circuit board.

14. The method of manufacture of claim 13 wherein the contact pads are soldered onto the printed circuit board using a convection remelting oven in which the electrical component is placed.

15. The electrical component of claim 8 wherein a minimal distance separating two adjacent turns of a segment of the electrical line carried by an arm of the armature as measured on the plane exterior face of said arm of the armature perpendicularly to the main axis is less than 250 μm.

16. The electrical component of claim 9 wherein a first portion of the armature and a second portion of the armature are defined, each portion of the armature being delimited in a first radial plane passing through the main axis and a second radial plane passing through the main axis and offset from the first radial plane, an offset angle between the first radial plane and the second radial plane being identical for the first portion of the armature and for the second portion of the armature, and a cumulative area of the turns in the first portion of the armature differs from a cumulative area of the turns in the second portion of the armature by less than 5%.

17. The method of manufacture of claim 13 further comprising distributing at least four arms of the armature in a loop around the central opening, each arm of the armature forming a respective exterior face that is part of the armature and extends parallel to the main axis and each arm carrying only one of the segments of the electrical line.

18. The method of manufacture of claim 13 further comprising distributing at least four branches of the armature in a loop around the main axis and delimiting a central hole through which the main axis passes, each branch of the printed circuit board carrying only one of the segments of the electrical line.

19. The method of manufacture of claim 13 further comprising connecting the first connection point of the electrical line to a first segment of the electrical line in the circulation direction, the first segment being carried by one of the branches of the printed circuit board.

20. The method of manufacture of claim 19 further comprising connecting a last segment of the electrical line in the circulation direction to the second connection point, the last segment being carried by an arm of the armature.
